(19) United States
(12) Patent Application Publication
(10) Pub. No.: US 2025/0101304 A1
(43) Pub. Date: Mar. 27, 2025

(54) ETCHANT COMPOSITIONS AND RELATED METHODS

(71) Applicant: ENTEGRIS, INC., Billerica, MA (US)

(72) Inventor: Qihui Qian, Danbury, CT (US)

(21) Appl. No.: 18/887,935

(22) Filed: Sep. 17, 2024

Related U.S. Application Data
(60) Provisional application No. 63/540,037, filed on Sep. 22, 2023.

(51) Int. Cl. C09K 13/08; H01L 21/306

(52) U.S. Cl. CPC C09K 13/08; H01L 21/30604

(57) ABSTRACT

Etchant compositions for selective etching of silicon germanium in the presence of silicon oxide and/or silicon nitride are provided. The etchant compositions may achieve passivation of at least one of silicon oxide, silicon nitride, or any combination thereof, while selectively etching silicon germanium, in a single step by applying the etchant composition to a substrate. The etchant compositions may comprise a halide compound; an oxidizing agent; a glycol solvent; 0.1% to 20% by weight of a surfactant based on a total weight of the etchant composition; and 0.01% to 10% by weight of an inhibitor based on the total weight of the etchant composition.

### CROSS-REFERENCE TO RELATED APPLICATIONS

This application claims the benefit under 35 USC 119 of U.S. Provisional Patent Application No. 63/540,037, filed Sep. 22, 2023, the disclosure of which is hereby incorporated herein by reference in its entirety.

### FIELD

The present disclosure relates to etchant compositions for selective etching and related methods.

### BACKGROUND

Manufacture of microelectronic devices involves material removal via etching. The removal of these materials via etching can also result in the undesirable removal of other materials.

### SUMMARY

Some embodiments relate to an etchant composition. In some embodiments, the etchant composition comprises a halide compound. In some embodiments, the etchant composition comprises an oxidizing agent. In some embodiments, the etchant composition comprises a glycol solvent. In some embodiments, the etchant composition comprises 0.1% to 20% by weight of a surfactant based on a total weight of the etchant composition. In some embodiments, the etchant composition comprises 0.01% to 10% by weight of an inhibitor based on the total weight of the etchant composition.

Some embodiments relate to a method for etching. In some embodiments, the method for etching comprises obtaining a substrate. In some embodiments, the substrate comprises a surface comprising silicone germanium. In some embodiments, the substrate comprises a surface comprising at least one of silicon oxide, silicon nitride, or any combination thereof. In some embodiments, the method for etching comprises obtaining an etchant composition. In some embodiments, the etchant composition comprises a halide compound. In some embodiments, the etchant composition comprises an oxidizing agent. In some embodiments, the etchant composition comprises a glycol solvent. In some embodiments, the etchant composition comprises 0.1% to 20% by weight of a surfactant based on a total weight of the etchant composition. In some embodiments, the etchant composition comprises 0.01% to 10% by weight of an inhibitor based on the total weight of the etchant composition. In some embodiments, the method for etching comprises contacting a substrate with the etchant composition to selectively remove silicon-germanium from the substrate.

Some embodiments relate to a method for forming an etchant composition. In some embodiments, the method for forming the etchant composition comprises obtaining at least one of a halide compound, an oxidizing agent, a glycol solvent, a surfactant, an inhibitor, water, or any combination thereof. In some embodiments, the method for forming the etchant composition comprises contacting at least one of the halide compound, the oxidizing agent, the glycol solvent, the surfactant, the inhibitor, water, or any combination thereof, so as to form an etchant composition.

### BRIEF DESCRIPTION OF THE FIGURES

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for selectively etching silicon germanium, according to some embodiments.

FIG. 2 is a flowchart of a method for forming an etchant composition, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “microelectronic device” (or “microelectronic device substrate,” or simply “substrate”) is used in a manner that is consistent with the generally understood meaning of this term in the electronics, microelectronics, and semiconductor fabrication arts, for example to refer to any of a variety of different types of: semiconductor substrates; integrated circuits; solid state memory devices; hard memory disks; read, write, and read-write heads and mechanical or electronic components thereof; flat panel displays; phase change memory devices; solar panels and other products that include one or more solar cell devices; photovoltaics; and microelectromechanical systems (MEMS) manufactured for use in microelectronic, integrated circuit, energy collection, or computer chip applications. It is to be understood that the term “microelectronic device” can refer to any in-process microelectronic device or microelectronic device substrate that contains or is being prepared to contain functional electronic (electrical-current-carrying) structures, functional semiconductor structures, and insulating structures, for eventual electronic use in a microelectronic device or microelectronic assembly.

As used herein, the term “silicon nitride” is given a meaning that is consistent with the meaning of the term as used in the microelectronics and semiconductor fabrication industries. Consistent therewith, silicon nitride refers to materials including thin films made of amorphous silicon nitride with commercially useful low levels of other materials or impurities and potentially some variation around the nominal stoichiometry of Si₃N₄. The silicon nitride may be present as part of a microelectronic device substrate as a functioning feature of the device, for example as a barrier layer or an insulating layer, or may be present to function as a material that facilitates a multi-step fabrication method for preparing a microelectronic device.

As used herein, the term “silicon oxide” is given a meaning that is consistent with the meaning of the term as used in the microelectronics and semiconductor fabrication industries. Consistent therewith, silicon oxide refers to thin films made of silicon oxide (SiOx), e.g., SiO₂, “thermal oxide” (ThOx), and the like. The silicon oxide can be placed on the substrate by any method, such as by being deposited by chemical vapor deposition from tetraethoxysilane (TEOS) or another source, or by being thermally deposited. The silicon oxide can advantageously contain a commercially useful low level of other materials or impurities. The silicon oxide may be present as part of a microelectronic device substrate as a feature of the microelectronic device, for example, as an insulating layer.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (isopropyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁₅ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀ alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃ alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₈-C₁₀ alkynyl, a C₂-C₉ alkynyl, a C₂-C₃ alkynyl, a C₂-C₇ alkynyl, a C₂-C₆ alkynyl, a C₂-C₅ alkynyl, a C₅-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Manufacture of microelectronic devices and fabrication of semiconductors can involve material removal via etching. Silicon germanium (SiGe) is an example of a material removed during the manufacture of microelectronic devices. For example, silicon germanium (SiGe) can be deposited as a layer on a substrate by chemical vapor deposition, among other vapor deposition processes. During the manufacture or fabrication process, the silicon germanium (SiGe) layer may be at least partially removed. Etchants may be useful for removing at least a portion of the silicon germanium (SiGe) layer. Current etchants, however, remove or otherwise damage other materials present, such as, for example and without limitation, silicon oxide (SiO₂, etc.) and silicon nitride (SiN), in addition to removing silicon germanium (SiGe). The removal of or damage caused to these other materials—including silicon oxide and silicon nitride—is undesirable.

Some embodiments relate to etchant compositions useful in the manufacture of microelectronics, including the fabrication of semiconductors. The etchant compositions disclosed herein exhibit a high selectivity for silicon germanium (SiGe), over other materials, including silicon oxide and silicon nitride. That is, for example, the etchant compositions disclosed herein are capable of removing silicon germanium (SiGe) without removing or otherwise damaging layers or surfaces comprising at least one of silicon oxide, silicon nitride, or any combination thereof. The etchant compositions may also exhibit a dual functionality in a single application. That is, for example, a single application of the etchant compositions disclosed herein is capable of passivating the silicon oxide and/or silicon nitride, while also etching the silicon germanium (SiGe) with a sufficiently high etch rate, and while preserving the silicon oxide and/or silicon nitride. In other words, the process of passivating and etching is capable of being achieved in a single step of a process. These and other advantages will become apparent from the disclosure herein.

The etchant compositions disclosed herein may comprise one or more components. In some embodiments, the etchant composition is a result of a combination of the one or more components. In some embodiments, the etchant composition is a composition comprising the one or more components. In some embodiments, the etchant composition is a mixture of the one or more components. In some embodiments, an etchant composition is derived from a formulation. In some embodiments, the etchant composition comprises a reaction product of a formulation, wherein the formulation comprises the one or more components which undergo a reaction. In some embodiments, the etchant composition comprises a dissolution product of a formulation, wherein the formulation comprises the one or more components, each of which independently undergo dissolution or solubilization (e.g., dissolving). In some embodiments, the formulation comprises one or more components, each of which are independently inert, wherein the one or more inert components do not undergo any physical or chemical change. In some embodiments, at least one of the one or more components disassociates in the etchant composition and/or the formulation.

The etchant compositions may comprise a solution. In some embodiments, the etchant composition comprises a liquid solution. In some embodiments, the etchant composition comprises a liquid solution and at least one solid component. In some embodiments, the etchant composition comprises a slurry. In some embodiments, the etchant composition comprises a suspension. In some embodiments, the etchant composition comprises an emulsion. In some embodiments, the etchant composition comprises a solution of at least one dissolved component. In some embodiments, the etchant composition comprises any combination of the foregoing.

The one or more components of the etchant composition may comprise a halide compound. Non-limiting examples of the halide compound include, for example and without limitation, at least one of hydrogen fluoride (HF), hexafluorosilicic acid (H₂SiF₆), ammonium fluoride (NH₄F), ammonium bifluoride (NH₄F₂), hydrogen chloride (HCl), hydrogen bromide (HBr), tetrafluoroboric acid, hexafluorosilicic acid, a compound comprising a boron-fluoride bond, a compound comprising a silicon-fluoride bond, tetrabutylammonium tetrafluoroborate (TBA-BF₄), tetraalkylammonium fluorides, or any combination thereof. In some embodiments, the halide compound comprises hydrogen fluoride (HF). In some embodiments, the halide compound comprises hexafluorosilicic acid (H₂SiF₆). In some embodiments, the halide compound comprises ammonium fluoride (NH₄F). In some embodiments, the halide compound comprises ammonium bifluoride (NH₄F₂). In some embodiments, the halide compound comprises hydrogen chloride (HCl). In some embodiments, the halide compound comprises hydrogen bromide (HBr).

The etchant composition may comprise 1% to 10% by weight of the halide compound based on the total weight of the etchant composition, or any range or subrange between 1% and 10%. In some embodiments, the etchant composition comprises 1% to 9.5%, 1% to 9%, 1% to 8.5%, 1% to 8%, 1% to 7.5%, 1% to 7%, 1% to 6.5%, 1% to 6%, 1% to 5.5%, 1% to 5%, 1% to 4.5%, 1% to 4%, 1% to 3.5%, 1% to 3%, 1% to 2.5%, 1% to 2%, or 1% to 1.5% by weight of the halide compound based on the total weight of the etchant composition. In some embodiments, the etchant composition comprises 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of the halide compound based on the total weight of the etchant composition. In some embodiments, the weight percentage is based on a total weight of the formulation.

The one or more components of the etchant composition may comprise an oxidizing agent. Non-limiting examples of the oxidizing agent include, for example and without limitation, at least one of acetic acid (CH₃COOH), hydrogen peroxide (H₂O₂), formic acid (CH₂O₂), peracetic acid (CH₃CO₃H), performic acid (CH₂O₃), or any combination thereof. In some embodiments, the oxidizing agent comprises acetic acid (CH₃COOH). In some embodiments, the oxidizing agent comprises hydrogen peroxide (H₂O₂). In some embodiments, the oxidizing agent comprises formic acid (CH₂O₂). In some embodiments, the oxidizing agent comprises peracetic acid (CH₃CO₃H). In some embodiments, the oxidizing agent comprises performic acid (CH₂O₃).

The etchant composition may comprise 20% to 80% by weight of the oxidizing agent based on the total weight of the etchant composition, or any range or subrange between 20% and 80%. In some embodiments, the etchant composition comprises comprise 20% to 75%, 20% to 70%, 20% to 65%, 20% to 60%, 20% to 55%, 20% to 50%, 20% to 45%, 20% to 40%, 20% to 35%, 20% to 30%, or 20% to 25% by weight of the oxidizing agent based on the total weight of the etchant composition. In some embodiments, the etchant composition comprises comprise 25% to 80%, 30% to 80%, 35% to 80%, 40% to 80%, 45% to 80%, 50% to 80%, 55% to 80%, 60% to 80%, 65% to 80%, 70% to 80%, or 75% to 80% by weight of the oxidizing agent based on the total weight of the etchant composition. In some embodiments, the weight percentage is based on a total weight of the formulation.

The one or more components of the etchant composition may comprise a glycol solvent. Non-limiting examples of the glycol solvent include, for example and without limitation, at least one of hexylene glycol, ethylene glycol, propylene glycol, or any combination thereof. In some embodiments, the glycol solvent comprises hexylene glycol. In some embodiments, the glycol solvent comprises ethylene glycol. In some embodiments, the glycol solvent comprises propylene glycol.

The etchant composition may comprise 1% to 30% by weight of a glycol solvent based on the total weight of the etchant composition, or any range or subrange between 1% and 30%. In some embodiments, the etchant composition comprises 1% to 28%, 1% to 26%, 1% to 25%, 1% to 24%, 1% to 22%, 1% to 20%, 1% to 18%, 1% to 16%, 1% to 15%, 1% to 14%, 1% to 12%, 1% to 10%, 1% to 8%, 1% to 6%, 1% to 5%, 1% to 4%, or 1% to 2% by weight of the glycol solvent based on the total weight of the etchant composition. In some embodiments, the etchant composition comprises 2% to 30%, 4% to 30%, 5% to 30%, 8% to 30%, 10% to 30%, 12% to 30%, 14% to 30%, 15% to 30%, 18% to 30%, 20% to 30%, 22% to 30%, 24% to 30%, 25% to 30%, or 28% to 30% by weight of the glycol solvent based on the total weight of the etchant composition. In some embodiments, the weight percentage is based on a total weight of the formulation.

The one or more components of the etchant composition may comprise a surfactant. In some embodiments, the surfactant comprises disulfonic acid. As used herein, the term “disulfonic acid” refers to a compound comprising sulfonic acid. In some embodiments, a sulfonic acid is an acid of the formula: —S(═O)(═O)OH. In some embodiments, a disulfonic acid comprises a compound of the formula: HO(O═)₂S—R—S(═O)₂OH, where R is an alkyl or an aryl, as defined herein. In some embodiments, R comprises a heteroatom, such as, for example and without limitation, at least one of O, N, S, or any combination thereof, and the like. Non-limiting examples of disulfonic acids include, for example and without limitation, at least one of a C₁₂ branched diphenyl oxide disulfonic acid, methanedisulfonic acid, ethanedisulfonic acid, 1,3-propanedisulfonic acid, or any combination thereof.

The etchant composition may comprise 1% to 20% by weight of the surfactant based on the total weight of the etchant composition, or any range or subrange between 1% and 20%. In some embodiments, the etchant composition comprises 1% to 19%, 1% to 18%, 1% to 17%, 1% to 16%, 1% to 15%, 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, or 1% to 2% by weight of the surfactant based on the total weight of the etchant composition. In some embodiments, the etchant composition comprises 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20% by weight of the surfactant based on the total weight of the etchant composition. In some embodiments, the weight percentage is based on a total weight of the formulation.

In some embodiments, the etchant composition comprises 1% to 10% by weight of the surfactant based on the total weight of the etchant composition, or any range or subrange between 1% and 10%. In some embodiments, the etchant composition comprises 1% to 9.5%, 1% to 9%, 1% to 8.5%, 1% to 8%, 1% to 7.5%, 1% to 7%, 1% to 6.5%, 1% to 6%, 1% to 5.5%, 1% to 5%, 1% to 4.5%, 1% to 4%, 1% to 3.5%, 1% to 3%, 1% to 2.5%, 1% to 2%, or 1% to 1.5% by weight of the surfactant based on the total weight of the etchant composition. In some embodiments, the etchant composition comprises 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of the surfactant based on the total weight of the etchant composition. In some embodiments, the weight percentage is based on a total weight of the formulation.

The one or more components of the etchant composition may comprise an inhibitor. Non-limiting examples of the inhibitor include, for example and without limitation, at least one of a polyethylenimine (PEI), a polyethylene, a polyvinylpyrrolidone, a silicic acid, a polyethylene glycol, or any combination thereof. In some embodiments, the inhibitor comprises a polyethylenimine. In some embodiments, the inhibitor comprises a polyethylene. In some embodiments, the inhibitor comprises a polyvinylpyrrolidone. In some embodiments, the inhibitor comprises a silicic acid. In some embodiments, the inhibitor comprises a polyethylene glycol.

The etchant composition may comprise 0.01% to 10% by weight of the inhibitor based on the total weight of the etchant composition, or any range or subrange between 0.01% and 10%. In some embodiments, the etchant composition comprises 0.001% to 9.5%, 0.01% to 9%, 0.01% to 8.5%, 0.01% to 8%, 0.01% to 7.5%, 0.01% to 7%, 0.01% to 6.5%, 0.01% to 6%, 0.01% to 5.5%, 0.01% to 5%, 0.01% to 4.5%, 0.01% to 4%, 0.01% to 3.5%, 0.01% to 3%, 0.01% to 2.5%, 0.01% to 2%, 0.01% to 1.5%, 0.01% to 1%, 0.01% to 0.8%, 0.01% to 0.6%, 0.01% to 0.5%, 0.01% to 0.4%, 0.01% to 0.2%, 0.01% to 0.1%, 0.01% to 0.08%, 0.01% to 0.06%, 0.01% to 0.05%, 0.01% to 0.04%, or 0.01% to 0.02% by weight of the inhibitor based on the total weight of the etchant composition. In some embodiments, the etchant composition comprises 0.1% to 10%, 1% to 10%, 1.5% to 10%, 2% to 10%, 2.5% to 10%, 3% to 10%, 3.5% to 10%, 4% to 10%, 4.5% to 10%, 5% to 10%, 5.5% to 10%, 6% to 10%, 6.5% to 10%, 7% to 10%, 7.5% to 10%, 8% to 10%, 8.5% to 10%, 9% to 10%, or 9.5% to 10% by weight of the inhibitor based on the total weight of the etchant composition. In some embodiments, the weight percentage is based on a total weight of the formulation.

In some embodiments, the etchant composition comprises 0.1% to 1.5% by weight of the inhibitor based on the total weight of the etchant composition, or any range or subrange between 0.1% and 1.5%. In some embodiments, the etchant composition comprises 0.1% to 1.4%, 0.1% to 1.3%, 0.1% to 1.2%, 0.1% to 1.1%, 0.1% to 1%, 0.1% to 0.9%, 0.1% to 0.8%, 0.1% to 0.7%, 0.1% to 0.6%, 0.1% to 0.5%, 0.1% to 0.4%, 0.1% to 0.3%, or 0.1% to 0.2% by weight of the inhibitor based on the total weight of the etchant composition. In some embodiments, the etchant composition comprises 0.2% to 1.5%, 0.3% to 1.5%, 0.4% to 1.5%, 0.5% to 1.5%, 0.6% to 1.5%, 0.7% to 1.5%, 0.8% to 1.5%, 0.9% to 1.5%, 1% to 1.5%, 1.1% to 1.5%, 1.2% to 1.5%, 1.3% to 1.5%, or 1.4% to 1.5% by weight of the inhibitor based on the total weight of the etchant composition. In some embodiments, the weight percentage is based on a total weight of the formulation.

In some embodiments, the one or more components may comprise water or any derivative thereof. The etchant composition may comprise at least 5% by weight of water based on the total weight of the etchant composition. For example, in some embodiments, the etchant composition comprises at least 1%, at least 3%, at least 5%, at least 10%, at least 15%, at least 20%, at least 25%, at least 30%, at least 35%, at least 40%, at least 40% by weight of water based on the total weight of the etchant composition. In some embodiments, the etchant composition comprises no greater than 50% by weight of water based on the total weight of the etchant composition. For example, in some embodiments, the etchant composition comprises no greater than 45%, no greater than 40%, no greater than 35%, no greater than 30%, no greater than 25%, no greater than 20%, no greater than 15%, no greater than 10%, or no greater than 5% by weight of water based on the total weight of the etchant composition.

The etchant composition may comprise 1% to 50% by weight of the water based on the total weight of the etchant composition, or any range or subrange between 1% to 50%. For example, in some embodiments, the etchant composition comprises 1% to 45%, 1% to 40%, 1% to 35%, 1% to 30%, 1% to 25%, 1% to 20%, 1% to 15%, 1% to 10%, 1% to 5%, 5% to 45%, 5% to 40%, 5% to 35%, 5% to 30%, 5% to 25%, 5% to 20%, 5% to 15%, 5% to 10%, 10% to 50%, 15% to 50%, 20% to 50%, 25% to 50%, 30% to 50%, 35% to 50%, 40% to 50%, 45% to 50%, 5% to 25%, 6% to 25%, 8% to 25%, 10% to 25%, 12% to 25%, 14% to 25%, 15% to 25%, 16% to 25%, 18% to 25%, 20% to 25%, 22% to 25%, 24% to 25%, 5% to 24%, 5% to 22%, 5% to 18% 5% to 16%, 5% to 14%, 5% to by weight of the water based on a total weight of the etchant composition.

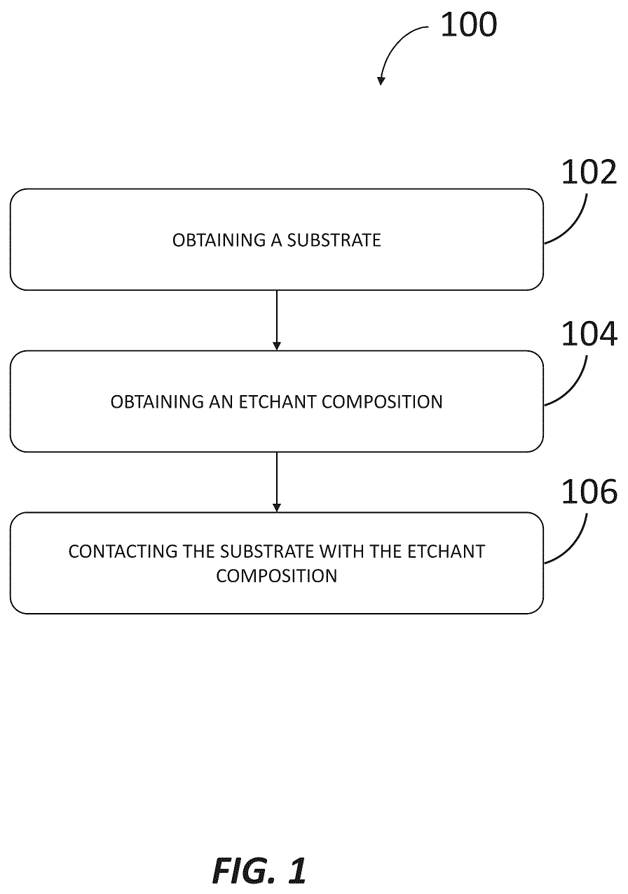

FIG. 1 is a flowchart of a method 100 for selectively etching silicon germanium, according to some embodiments. As shown in FIG. 1, in some embodiments, the methods 100 may comprise one or more of the following steps: a step 102 of obtaining a substrate; a step 104 of obtaining an etchant composition; a step 108 of contacting the substrate with the etchant composition.

At step 102, in some embodiments, a substrate is obtained. The substrate may comprise at least one of silicon nitride, silicon oxide, polysilicon, or any combination thereof. In some embodiments, the substrate comprises a surface comprising silicon nitride. In some embodiments, the substrate comprises a surface comprising silicon oxide. In some embodiments, the substrate comprises a surface comprising polysilicon. The substrate may comprise other materials, including surfaces comprising other materials. The substrate can contain other materials that are useful in a microelectronic device, such as one or more of an insulating material, barrier layer, conducting material, semiconducting material, a metal silicide, or a material that is useful for processing a microelectronic device (e.g., photoresist, mask, among others). Examples of substrates include those having a surface that includes at least one of silicon nitride, thermal oxide (ThOx), PETEOS (oxide deposited using plasma enhanced tetraethyl ortho silicate), polysilicon, or any combination thereof.

In some embodiments, the substrate comprises alternating thin film layers of silicon nitride. In some embodiments, the substrate comprises layers of silicon nitride layers alternating with at least one of layers of silicon oxide, layers of polysilicon, layers of conductive metal silicides, layers of dielectrics (e.g., such as zirconium oxide or aluminum oxide), or any combination thereof. Prior to the contacting with the etchant composition, the substrate comprises the alternating layers of silicon nitride positioned in openings between high aspect ratio silicon oxide structures.

At step 104, in some embodiments, an etchant composition is obtained. Any of the etchant compositions disclosed herein may be used. For example, in some embodiments, the etchant composition comprises at least one of a halide compound; an oxidizing agent; a glycol solvent; 0.1% to 20% by weight of a surfactant based on a total weight of the etchant composition; 0.01% to 10% by weight of an inhibitor based on the total weight of the etchant composition, or any combination thereof. It will be appreciated that other etchant compositions disclosed herein may be used without departing from this disclosure.

At step 106, in some embodiments, the substrate is contacted with the etchant composition. The contacting may comprise applying the etchant composition to the surface by at least one of spraying the etchant composition onto the surface; dipping (in a static or dynamic volume of the etchant composition) the substrate into etchant composition; contacting the surface with another material (e.g., a pad, or fibrous sorbent applicator element, that has etchant composition absorbed thereon); contacting the substrate with an amount of the etchant composition in a circulating pool; submersing the substrate in the etchant composition; or any combination thereof, among other techniques in which the etchant composition is brought into removal contact with the surface of the microelectronic substrate that contains silicon. The application may be in a batch or single wafer apparatus, for dynamic or static cleaning.

The selective etching of silicon germanium using the etchant composition may proceed in the presence of silicon oxide and/or silicon nitride, as mentioned above. In addition to silicon oxide and silicon nitride, the selective etching of silicon germanium using the etchant composition may proceed in the presence of other materials, while maintaining selectivity for silicon germanium. Examples of these other materials include, without limitation, at least one of conductive materials, semiconducting materials, insulating materials, processing materials, or any combination thereof. In some embodiments, a metal silicide is present during the selective etching of silicon germanium. In some embodiments, the metal silicide is present but not exposed during the selective etching of silicon germanium.

The conditions of the contacting may comprise at least one of a duration, a temperature, or any combination thereof. The duration should be sufficient to selectively remove the silicon germanium. The duration of exposure to the etchant composition and the temperature of the etchant composition may be selected based on a desired amount of removal of the silicon germanium from a surface of the substrate. The duration of the contacting should balance process control and quality with process efficiency and throughput of the etching process and the semiconductor fabrication line. Examples of a suitable duration may be in a range of 5 minutes to 300 minutes, or any range or subrange therebetween, such as, 10 minutes to 60 minutes. Examples of a suitable temperature is a temperature in a range of 100° C. to 250° C. (e.g., 100° C. to 180° C., 150° C. to 180° C.), or any range or subrange therebetween. Such contacting times and temperatures are illustrative, and other suitable contacting times and temperature conditions may be used herein without departing from this disclosure.

By contacting the substrate with the etchant composition, the etchant composition may passivate at least one of a surface comprising silicon nitride, a surface comprising silicon oxide, or any combination thereof. In some embodiments, passivating a surface comprises modifying the surface so as to reduce a reactivity of the surface—for example, when in the presence of substances that etch silicon germanium. In some embodiments, at least one of the halide compound, the oxidizing agent, the glycol solvent, the surfactant, the inhibitor, or any combination thereof, when in a presence of a surface comprising silicon nitride, modifies or is configured to modify the surface comprising silicon nitride, so as to reduce a reactivity of the surface comprising silicon nitride. In some embodiments, at least one of the halide compound, the oxidizing agent, the glycol solvent, the surfactant, the inhibitor, or any combination thereof, when in a presence of a surface comprising silicon oxide, modifies or is configured to modify the surface comprising silicon oxide, so as to reduce a reactivity of the surface comprising silicon oxide. In some embodiments, the etchant composition passivates surfaces other than silicon nitride and/or silicon oxide.

The etchant composition may exhibit a selectivity for silicon germanium relative to silicon nitride of at least 5, at least 20, at least 150, at least 200, at least 500, at least 1000, at least 2000, at least 4000, or greater. In some embodiments, for example, the etchant composition exhibits a selectivity for silicon germanium relative to silicon nitride of 5:1 to 5000:1, or any range or subrange therebetween. The etchant composition may exhibit a selectivity for silicon germanium relative to silicon oxide of at least 5, at least 20, at least 150, at least 200, at least 500, at least 1000, at least 2000, at least 4000, or greater. In some embodiments, for example, the etchant composition exhibits a selectivity for silicon germanium relative to silicon oxide of 5:1 to 5000:1, or any range or subrange therebetween. In some embodiments, the etchant composition's selectivity for silicon germanium relative to silicon nitride and/or silicon oxide is the same or similar. In some embodiments, the etchant composition's selectivity for silicon germanium relative to silicon nitride and/or silicon oxide is different.

The etchant composition may remove at least a portion of the surface comprising silicon germanium.

After contacting the substrate with the etchant composition, excess etchant composition and other substances may be rinsed, washed, or otherwise removed from the surfaces using water (e.g., deionized water) at a temperature in a range of 20° C. to 90° C., or any range or subrange therebetween, followed by drying (e.g., spin drying, contacting with nitrogen (N₂), air drying, etc.).

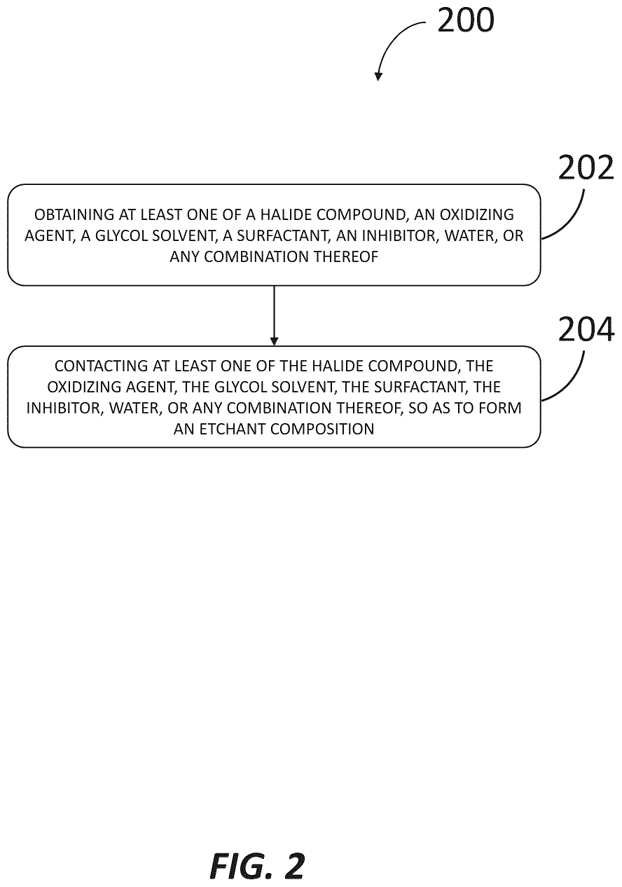

FIG. 2 is a flowchart of a method 200 for forming an etchant composition, according to some embodiments. As shown in FIG. 2, in some embodiments, the method 200 for forming an etchant composition comprises one or more of the following steps: a step 202 of obtaining at least one of a halide compound, an oxidizing agent, a glycol solvent, a surfactant, an inhibitor, water, or any combination thereof; a step 204 of contacting at least one of the halide compound, the oxidizing agent, the glycol solvent, the surfactant, the inhibitor, water, or any combination thereof, so as to form an etchant composition. In some embodiments, the contacting is performed under heating to a temperature in a range of 20° C. to 200° C., 20° C. to 180° C., 20° C. to 160° C., 20° C. to 140° C., 20° C. to 120° C., 20° C. to 100° C., 20° C. to 80° C., 20° C. to 60° C., 20° C. to 40° C., 40° C. to 200° C., 60° C. to 200° C., 80° C. to 200° C., 100° C. to 200° C., 120° C. to 200° C., 140° C. to 200° C., 160° C. to 200° C., or 180° C. to 200° C., or any range or subrange therebetween. In some embodiments, the contacting comprising mixing, combining, adding, or otherwise bringing into close or immediate proximity so as to form the etchant composition. It will be appreciated that any of the one or more components disclosed herein may be included in the etchant composition without departing from this disclosure.

### ASPECTS

Various Aspects are described below. It is to be understood that any one or more of the features recited in the following Aspect(s) can be combined with any one or more other Aspect(s).
Aspect 1. An etchant composition comprising:
   a halide compound;
   an oxidizing agent;
   a glycol solvent;
   0.1% to 20% by weight of a surfactant based on a total weight of the etchant composition; and
   0.01% to 10% by weight of an inhibitor based on the total weight of the etchant composition.
Aspect 2. The etchant composition according to Aspect 1, wherein the halide compound comprises at least one of hydrogen fluoride, hexafluorosilicic acid, NH₄F, NH₄F₂, HCl, HBr, or any combination thereof.
Aspect 3. The etchant composition according to any one of Aspects 1-2, wherein the oxidizing agent comprises at least one of acetic acid, hydrogen peroxide, formic acid, peracetic acid, performic acid, or any combination thereof.
Aspect 4. The etchant composition according to any one of Aspects 1-3, wherein the glycol solvent comprises at least one of hexylene glycol, ethylene glycol, propylene glycol, or any combination thereof.
Aspect 5. The etchant composition according to any one of Aspects 1-4, wherein the surfactant comprises a disulfonic acid.
Aspect 6. The etchant composition according to any one of Aspects 1-5, wherein the inhibitor comprises a polyethylenimine, a polyethylene, a polyvinylpyrrolidone, a silicic acid, a polyethylene glycol, or any combination thereof.
Aspect 7. The etchant composition according to any one of Aspects 1-6, further comprising water.
Aspect 8. The etchant composition according to any one of Aspects 1-7, wherein the etchant composition comprises 1% to 10% by weight of the halide compound based on the total weight of the etchant composition.
Aspect 9. The etchant composition according to any one of Aspects 1-8, wherein the etchant composition comprises 20% to 80% by weight of the oxidizing agent based on the total weight of the etchant composition.
Aspect 10. The etchant composition according to any one of Aspects 1-9, wherein the etchant composition comprises 1% to 30% by weight of a glycol solvent based on the total weight of the etchant composition.
Aspect 11. The etchant composition according to any one of Aspects 1-10, wherein the etchant composition comprises 1% to 10% by weight of the surfactant based on the total weight of the etchant composition.
Aspect 12. The etchant composition according to Aspect 11, wherein the surfactant comprises a disulfonic acid.
Aspect 13. The etchant composition according to any one of Aspects 1-12, wherein the etchant composition comprises 0.1% to 1.5% by weight of the inhibitor based on the total weight of the etchant composition.
Aspect 14. The etchant composition according to Aspect 13, wherein the inhibitor comprises polyethylenimine.
Aspect 15. The etchant composition according to any one of Aspects 1-14, wherein the etchant composition comprises:
   1% to 10% of the surfactant based on the total weight of the etchant composition; and
   0.1% to 1.5% of the inhibitor based on the total weight of the etchant composition.
Aspect 16. The etchant composition according to Aspect 15, wherein the surfactant comprises a disulfonic acid and wherein the inhibitor comprises polyethylenimine.
Aspect 17. A method for etching, the method comprising:
   obtaining a substrate, the substrate comprising:
      a surface comprising silicone germanium;
      a surface comprising at least one of silicon oxide, silicon nitride, or any combination thereof;
   obtaining an etchant composition comprising:
      a halide compound;
      an oxidizing agent;
      a glycol solvent;
      0.1% to 20% by weight of a surfactant based on a total weight of the etchant composition;
      0.01% to 10% by weight of an inhibitor based on the total weight of the etchant composition;
   contacting a substrate with the etchant composition to selectively remove silicon-germanium from the substrate.
Aspect 18. The method according to Aspect 17, wherein the etchant composition exhibits a selectivity for silicon germanium over silicone of at least 20.
Aspect 19. The method according to any one of Aspects 17-18, wherein the etchant composition exhibits a selectivity for silicone germanium over silicon oxide of at least 5.
Aspect 20. The method according to any one of Aspects 17-19, wherein the etchant composition exhibits a selectivity for silicon germanium over silicon nitride of at least 5.

### Example 1

### Base Formulation

Various etchant compositions were prepared and compared to a control composition. The formulations for the etchant compositions, as well as the control composition are summarized in Table 1 below. The control composition was prepared from a base formulation comprising hydrogen fluoride, hydrogen peroxide, water, acetic acid, formic acid, and H₂SO₄.

TABLE 1

| Sample | Formulation |
|---|---|
| Control Composition | Base Formulation (“Base”) |
| Etchant Composition 1 | Base + 2% Disulfonic Acid |
| Etchant Composition 2 | Base + 10% Disulfonic Acid |
| Etchant Composition 3 | Base + 20% Disulfonic Acid |
| Etchant Composition 4 | Base + 0.1% PEI + Hexylene Glycol |
| Etchant Composition 5 | Base + 0.5% PEI + Hexylene Glycol |
| Etchant Composition 6 | Base + 2% PEI + Hexylene Glycol |
| Etchant Composition 7 | Base + 1% Disulfonic Acid + 0.5% |
| | PEI + Hexylene Glycol |
| Etchant Composition 8 | Base + 10% Disulfonic Acid + 0.5% |
| | PEI + Hexylene Glycol |
| Etchant Composition 9 | Base + 20% Disulfonic Acid + 0.5% |
| | PEI + Hexylene Glycol |
| Etchant Composition 10 | Base + 10% Disulfonic Acid + 0.1% |
| | PEI + Hexylene Glycol |
| Etchant Composition 11 | Base + 10% Disulfonic Acid + 2% |
| | PEI + Hexylene Glycol |

The etch rate for each of the etchant compositions summarized in Table 1, including the control composition, was measured for various substrates. The corresponding selectivity, based on the measured etch rates, is summarized in Table 2.

TABLE 2

| Sample | SiGe¹⁵/Si | SiGe¹⁵/ToX | SiGe¹⁵/SiN |
|---|---|---|---|
| Control | 21 | 3 | 33 |
| Composition | | | |
| Etchant | 49 | 2 | >1000 |
| Composition 1 | | | |
| Etchant | 115 | 2 | >1000 |
| Composition 2 | | | |
| Etchant | 76 | 2 | >1000 |
| Composition 3 | | | |
| Etchant | 16 | 3 | 18 |
| Composition 4 | | | |
| Etchant | 16 | 9 | 19 |
| Composition 5 | | | |
| Etchant | 16 | 14 | 16 |
| Composition 6 | | | |
| Etchant | 42 | 6 | 56 |
| Composition 7 | | | |
| Etchant | 111 | 19 | >1000 |
| Composition 8 | | | |
| Etchant | 100 | 18 | >1000 |
| Composition 9 | | | |
| Etchant | 28 | 7 | >1000 |
| Composition 10 | | | |
| Etchant | 26 | 17 | >1000 |
| Composition 11 | | | |

As shown above in Table 2, the etchant compositions unexpectedly exhibited improved selectivity for SiGe over Si relative to the control. In addition, the etchant compositions unexpectedly exhibited improved selectivity for SiGe over thermal oxide relative to the control. Finally, the etchant compositions unexpectedly exhibited improved selectivity for SiGe over SiN relative to the control.

What is claimed is:

1. An etchant composition comprising:
a halide compound;
an oxidizing agent;
a glycol solvent;
0.1% to 20% by weight of a surfactant based on a total weight of the etchant composition; and
0.01% to 10% by weight of an inhibitor based on the total weight of the etchant composition.

2. The etchant composition of claim 1, wherein the halide compound comprises at least one of hydrogen fluoride, hexafluorosilicic acid, NH₄F, NH₄F₂, HCl, HBr, or any combination thereof.

3. The etchant composition of claim 1, wherein the oxidizing agent comprises at least one of acetic acid, hydrogen peroxide, formic acid, peracetic acid, performic acid, or any combination thereof.

4. The etchant composition of claim 1, wherein the glycol solvent comprises at least one of hexylene glycol, ethylene glycol, propylene glycol, or any combination thereof.

5. The etchant composition of claim 1, wherein the surfactant comprises a disulfonic acid.

6. The etchant composition of claim 1, wherein the inhibitor comprises a polyethylenimine, a polyethylene, a polyvinylpyrrolidone, a silicic acid, a polyethylene glycol, or any combination thereof.

7. The etchant composition of claim 1, further comprising water.

8. The etchant composition of claim 1, wherein the etchant composition comprises 1% to 10% by weight of the halide compound based on the total weight of the etchant composition.

9. The etchant composition of claim 1, wherein the etchant composition comprises 20% to 80% by weight of the oxidizing agent based on the total weight of the etchant composition.

10. The etchant composition of claim 1, wherein the etchant composition comprises 1% to 30% by weight of a glycol solvent based on the total weight of the etchant composition.

11. The etchant composition of claim 1, wherein the etchant composition comprises 1% to 10% by weight of the surfactant based on the total weight of the etchant composition.

12. The etchant composition of claim 11, wherein the surfactant comprises a disulfonic acid.

13. The etchant composition of claim 1, wherein the etchant composition comprises 0.1% to 1.5% by weight of the inhibitor based on the total weight of the etchant composition.

14. The etchant composition of claim 13, wherein the inhibitor comprises polyethylenimine.

15. The etchant composition of claim 1, wherein the etchant composition comprises:
1% to 10% of the surfactant based on the total weight of the etchant composition; and
0.1% to 1.5% of the inhibitor based on the total weight of the etchant composition.

16. The etchant composition of claim 15, wherein the surfactant comprises a disulfonic acid and wherein the inhibitor comprises polyethylenimine.

17. A method for etching, the method comprising:
obtaining a substrate, the substrate comprising:
a surface comprising silicone germanium;
a surface comprising at least one of silicon oxide, silicon nitride, or any combination thereof;
obtaining an etchant composition comprising:
a halide compound;
an oxidizing agent;
a glycol solvent;
0.1% to 20% by weight of a surfactant based on a total weight of the etchant composition;
0.01% to 10% by weight of an inhibitor based on the total weight of the etchant composition;
contacting a substrate with the etchant composition to selectively remove silicon-germanium from the substrate.

18. The method of claim 17, wherein the etchant composition exhibits a selectivity for silicon germanium over silicone of at least 20.

19. The method of claim 17, wherein the etchant composition exhibits a selectivity for silicone germanium over silicon oxide of at least 5.

20. The method of claim 17, wherein the etchant composition exhibits a selectivity for silicon germanium over silicon nitride of at least 5.
